(19) United States
(12) Patent Application Publication
(10) Pub. No.: US 2025/0031553 A1
(43) Pub. Date: Jan. 23, 2025

(54) DISPLAY DEVICE AND METHOD FOR MANUFACTURING THE SAME

(71) Applicant: Samsung Display Co., LTD., Yongin-si (KR)

(72) Inventors: Seung Wook KWON, Yongin-si (KR); Hee Chang YOON, Yongin-si (KR); Hyo Jeong KWON, Yongin-si (KR)

(21) Appl. No.: 18/634,706

(22) Filed: Apr. 12, 2024

(30) Foreign Application Priority Data
Jul. 21, 2023 (KR) 10-2023-0095455

(51) Int. Cl. H10K 59/80; H10K 59/12

(52) U.S. Cl. CPC H10K 59/873; H10K 59/1201

(57) ABSTRACT

A display device and a method of fabricating the same are provided. The display device includes a substrate, a light emitting element layer disposed on the substrate and including a pixel electrode, an organic layer, and a common electrode, an encapsulation layer disposed on the light emitting element layer, and a passivation layer disposed on the encapsulation layer. A contact angle between a surface of the passivation layer and water ranges from 5° to 45°.

### CROSS-REFERENCE TO RELATED APPLICATION

This application claims priority to Korean Patent Application No. 10-2023-0095455, filed on Jul. 21, 2023, and all the benefits accruing therefrom under 35 U.S.C. § 119, the content of which in its entirety is herein incorporated by reference.

### BACKGROUND

### 1. Technical Field

The present disclosure relates to a display device and a method for manufacturing the same.

### 2. Description of the Related Art

The importance of a display device is increasing with the development of multimedia. Accordingly, various types of display devices such as, for example, an organic light emitting display (OLED) and a liquid crystal display (LCD) are being used.

With the development of display technology, research and development on a display device having a flexible display is being actively conducted. For some flexible displays, a display screen may be extended or shortened by folding, bending, or sliding the display screen, which may greatly contribute to reducing a volume or changing the design of the display device.

Some display devices are manufactured by obtaining a plurality of cells by performing a sheet unit process on a mother substrate including a plurality of cells corresponding to each display device, and performing a module unit process on the obtained cells. In some cases, when the cell is transferred from the sheet unit process to the module unit process, an upper passivation layer may be formed on a cell surface to prevent physical and chemical scratches that may occur during the movement process, and the cell may then be moved.

### SUMMARY

Aspects of the present disclosure provide a display device capable of reducing damage to a lower passivation layer and a defect in peeling when an acid-resistant film or passivation layer is peeled off, and a method for manufacturing the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate, a light emitting element layer disposed on the substrate and including a pixel electrode, an organic layer, and a common electrode, an encapsulation layer disposed on the light emitting element layer, and a passivation layer disposed on the encapsulation layer, where a contact angle between a surface of the passivation layer and water ranges from 5° to 45°.

In an embodiment, the surface of the passivation layer may have hydrophilicity.

In an embodiment, the passivation layer may include one or more of an acrylic resin, an epoxy resin, and a urethane resin.

In an embodiment, the passivation layer may be formed to have a thickness of 8 μm to 30 μm.

In an embodiment, the encapsulation layer may include a first encapsulation layer disposed on the light emitting element layer, a second encapsulation layer disposed on the first encapsulation layer, and a third encapsulation layer disposed on the second encapsulation layer, and the passivation layer is in contact with an upper surface of the third encapsulation layer.

According to an aspect of the present disclosure, a method for manufacturing a display device includes forming a display layer on a mother substrate, applying a first coating layer on the display layer, forming a first passivation layer by sequentially performing a first UV curing process, a heat treatment process, and a plasma treatment process on the first coating layer, and forming a second passivation layer on the first passivation layer, where the plasma treatment process uses N2 plasma.

In an embodiment, the first coating layer may be applied through an inkjet printing process.

In an embodiment, the first coating layer may be applied such that a thickness of the first coating layer may be 8 μm to 30 μm.

In an embodiment, a cumulative amount of light of the first UV curing process may be 0.5 J to 3 J.

In an embodiment, the heat treatment process may be performed for 10 minutes to 40 minutes at a temperature range of 70° C. to 90° C.

In an embodiment, the plasma treatment process may be performed at a power of 1 kW to 5 kW, a voltage of 11 kV to 15 kV, and a speed of 60 mm/s to 260 mm/s.

In an embodiment, a flow rate of N2 gas of the N2 plasma may be 200 LPM to 1200 LPM.

In an embodiment, the second passivation layer may be formed by applying a second coating layer on the first passivation layer and performing a second UV curing process.

In an embodiment, the method may further include attaching an acid-resistant film onto the second passivation layer, etching the mother substrate, performing a third UV curing process on the acid-resistant film, removing the acid-resistant film, cutting the mother substrate into units of cells, and removing the second passivation layer.

In an embodiment, the etching of the mother substrate may include spraying an etchant on the mother substrate to reduce a thickness of the mother substrate.

According to an aspect of the present disclosure, a method for manufacturing a display device includes forming a display layer on a mother substrate, forming a first passivation layer by applying a first coating layer on the display layer and sequentially performing a first UV curing process, a first heat treatment process, and a first plasma treatment process on the first coating layer, forming a second passivation layer by applying a second coating layer on the first passivation layer and sequentially performing a second UV curing process, a second heat treatment process, and a second plasma treatment process on the second coating layer, and forming a third passivation layer on the second passivation layer, where the first plasma treatment process and the second plasma treatment process use N2 plasma.

In an embodiment, the first plasma treatment process and the second plasma treatment process may be performed at a power of 1 kW to 5 kW, a voltage of 11 kV to 15 kV, and a speed of 60 mm/s to 260 mm/s.

In an embodiment, a flow rate of N2 gas of the N2 plasma may be 200 LPM to 1200 LPM.

In an embodiment, the method may further include attaching an acid-resistant film onto the third passivation layer and etching the mother substrate, performing a third UV curing process on the acid-resistant film, simultaneously removing the acid-resistant film and the third passivation layer, cutting the mother substrate into units of cells, and removing the second passivation layer.

In an embodiment, forming the third passivation layer comprises may include applying a third coating layer on the first passivation layer, where the first coating layer, the second coating layer, and the third coating layer are each applied through an inkjet printing process.

According to one or more embodiments of the display device and the method for manufacturing the same, it is possible to prevent a second passivation layer from being torn or a first passivation layer and/or prevent an encapsulation layer from being torn when the second passivation layer is peeled off, by improving a curing rate of the first passivation layer through a UV curing process, a heat treatment process, and a plasma treatment process.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a cross-sectional view of the display device of FIG. 1 viewed from a side;

FIG. 3 is a plan view illustrating a display layer of the display device according to an embodiment;

FIG. 4 is a plan view illustrating a display area of a display panel according to an embodiment;

FIG. 5 is an enlarged plan view of area A of FIG. 4;

FIG. 6 is a cross-sectional view taken along line X1-X1′ of FIG. 5;

FIG. 7 is a flowchart illustrating a method for manufacturing a display device according to an embodiment;

FIG. 8 is a flowchart illustrating steps of forming a first passivation layer according to an embodiment;

FIGS. 9 to 20 are views illustrating example processes of a method for manufacturing a display device according to an embodiment.

FIG. 21 is a flowchart illustrating a method for manufacturing a display device according to another embodiment;

FIGS. 22 to 26 are views illustrating example processes of a method for manufacturing a display device according to another embodiment;

FIG. 27 is a graph illustrating a peeling force between a first passivation layer and a second passivation layer according to distance from an end of the first passivation layer; and

FIG. 28 is a graph of FT-IR analysis of a coating solution and a passivation layer.

### DETAILED DESCRIPTION

The present invention will now be described more fully hereinafter with reference to the accompanying drawings, in which example embodiments of the invention are shown. This invention may, however, be embodied in different forms and should not be construed as limited to the embodiments set forth herein. Rather, these embodiments are provided such that this disclosure will be thorough and complete, and will fully convey the scope of the invention to those skilled in the art.

It will also be understood that when a layer is referred to as being “on” another layer or substrate, the layer can be directly on the other layer or substrate, or intervening layers may also be present. The same reference numbers indicate the same or like components throughout the specification.

It will be understood that, although the terms “first,” “second,” and the like may be used herein to describe various elements, these elements are not to be limited by these terms. These terms as used herein may distinguish one element from another element and are not to be limited by the terms. For instance, a first element discussed below could be termed a second element without departing from the teachings of the present invention. Similarly, the second element could also be termed the first element. The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

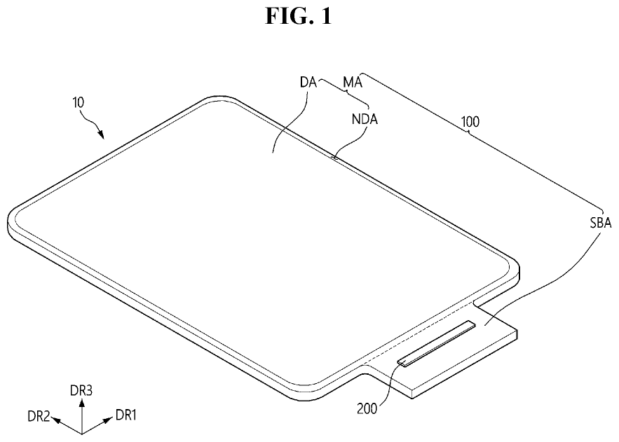

FIG. 1 is a perspective view illustrating a display device according to an embodiment.

Referring to FIG. 1, a display device 10 may display a moving image or a still image. The display device 10 may refer to any electronic device that provides a display screen. For example, the display device 10 may include televisions, laptop computers, monitors, billboards, Internet of things, mobile phones, smartphones, tablet personal computers (PCs), electronic watches, smartwatches, watch phones, head mounted displays, mobile communication terminals, electronic notebooks, electronic books, portable multimedia players (PMPs), navigation, game consoles, digital cameras, camcorders, vehicle navigation, vehicle dashboards, and the like that provide a display screen. In the present specification, the display device 10 may be a display device for a vehicle and may be provided in a vehicle, but is not limited thereto.

Examples of the display device 10 may include an inorganic light emitting diode display device, an organic light emitting display device, a quantum dot light emitting display device, a plasma display device, and a field emission display device. Hereinafter, it is illustrated that an organic light emitting diode display device is used as an example of the display device, but the present disclosure is not limited thereto. Aspects of the present disclosure described with reference to an organic light emitting diode display device may be applied to other display devices as long as the same technical idea is applicable thereto.

A shape of the display device 10 may be variously changed. For example, the display device 10 may have a shape similar to a quadrangle having a side in a first direction DR1 and a side in a second direction DR2. A corner where the side in the first direction DR1 and the side in the second direction DR2 meet may be rounded to have a curvature, but is not limited thereto. For example, the corner may be formed at a right angle. The planar shape of the display device 10 is not limited to a quadrangle, and the display device 10 may be formed such that the display device 10 is polygonal shaped, circular shaped, or oval shaped.

The display device 10 may include a display area DA and a non-display area NDA. The display area DA is an area in which a screen may be displayed, and the non-display area NDA is an area in which a screen is not displayed. The display area DA may also be referred to as an active area, and the non-display area NDA may also be referred to as a non-active area. The display area DA may generally occupy the center of the display device 10.

The display device 10 includes a display panel 100, a display driver 200, and a circuit board 300.

The display panel 100 may include a main area MA and a sub-area SBA.

The main area MA may include the display area DA and the non-display area NDA disposed around the display area DA. The display area DA may include pixels capable of displaying an image. The display area DA may emit light from a plurality of light emitting areas or a plurality of opening areas. For example, the display panel 100 may include a pixel circuit including switching elements, a pixel defining film defining the light emitting areas or the opening areas, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto.

The non-display area NDA may be an area outside the display area DA. The non-display area NDA may be defined as an edge area of the main area MA of the display panel 100. The non-display area NDA may include a gate driver (not illustrated) supplying gate signals to gate lines, and the non-display area NDA may include fan-out lines (not illustrated) connecting the display driver 200 and the display area DA.

The sub-area SBA may be an area extending from one side of the main area MA. The sub-area SBA may include a flexible material that may be bent, folded, rolled, or the like. For example, when the sub-area SBA is bent, the sub-area SBA may overlap the main area MA in a thickness direction (a third direction DR3). The sub-area SBA may include the display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may supply data voltages to the data lines. The display driver 200 may supply a power voltage to the power line and may supply a gate control signal to the gate driver. The display driver 200 may be formed as an integrated circuit (IC) and mounted by a chip on glass (COG) method, a chip on plastic (COP) method, or an ultrasonic bonding method. For example, the display driver 200 may be disposed in the sub-area SBA, and the display driver 200 may overlap the main area MA in the thickness direction by bending of the sub-area SBA. As another example, the display driver 200 may be mounted on the circuit board 300.

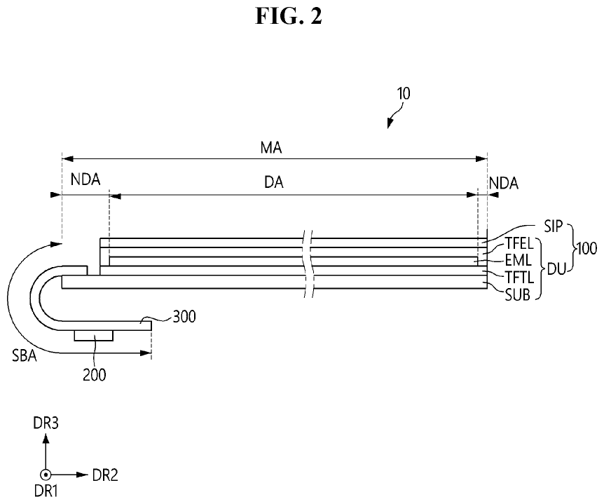

A circuit board 300 later illustrated at FIG. 2 may be attached onto the pad portion of the display panel 100 using an anisotropic conductive film (ACF). Lead lines of the circuit board 300 may be electrically connected to the pad portion of the display panel 100. The circuit board 300 may be a flexible film such as, for example, a flexible printed circuit board, a printed circuit board, or a chip on film.

FIG. 2 is a cross-sectional view of the display device 10 of FIG. 1 viewed from a side.

Referring to FIG. 2, the display panel 100 may include a display layer DU and a passivation layer SIP disposed on the display layer DU. The display layer DU may include a substrate SUB, a thin film transistor layer TFTL, a light emitting element layer EML, and an encapsulation layer TFEL.

The substrate SUB may be a base substrate or a base member. The substrate SUB may be a glass substrate. However, the substrate SUB is not limited thereto and may be any suitable flexible substrate that may be bent, folded, rolled, or the like. For example, the substrate SUB may include a polymer resin such as, for example, polyimide PI, but is not limited thereto.

The thin film transistor layer TFTL may be disposed on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines connecting the display driver 200 and the data lines, and lead lines connecting the display driver 200 and the pad portion. Each of the thin film transistors may include a semiconductor area, a source electrode, a drain electrode, and a gate electrode. For example, when the gate driver is formed on one side of the non-display area NDA of the display panel 100, the gate driver may include the thin film transistors.

The thin film transistor layer TFTL may be disposed in the display area DA, the non-display area NDA, and the sub-area SBA. The thin film transistors, the gate lines, the data lines, and the power lines of each of the pixels of the thin film transistor layer TFTL may be disposed in the display area DA. The gate control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include a plurality of light emitting elements including a first electrode, a second electrode, and a light emitting layer to emit light, and a pixel defining film defining pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be combined with each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

An encapsulation layer TFEL may cover an upper surface and side surfaces of the light emitting element layer EML and may protect the light emitting element layer EML. The encapsulation layer TFEL may include at least one inorganic film and at least one organic film for encapsulating the light emitting element layer EML.

The passivation layer SIP may be disposed on the encapsulation layer TFEL. The passivation layer SIP may planarize a level difference of the display layer DU on a lower side of the passivation layer SIP (e.g., planarize an upper surface of the display layer DU, reduce level differences on the upper surface of the display layer DU) and absorb a portion of light introduced from the outside to reduce reflected light caused by external light.

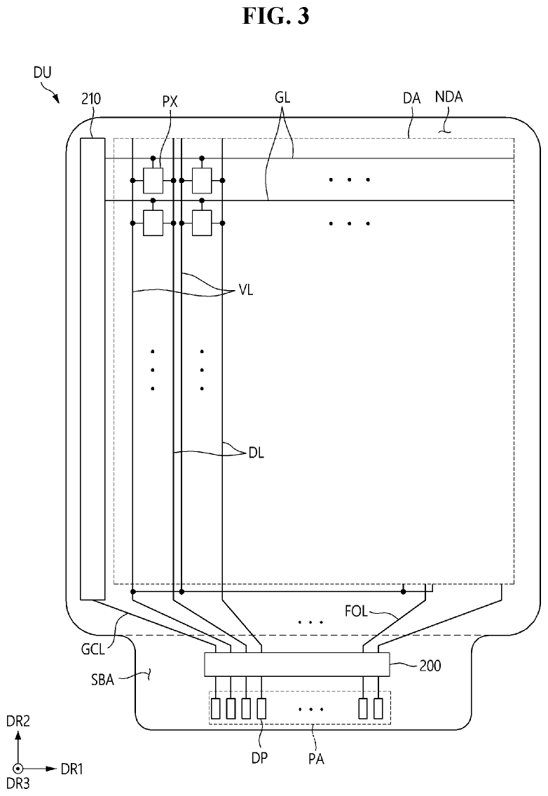

FIG. 3 is a plan view illustrating a display layer DU of the display device 10 according to an embodiment.

Referring to FIG. 3, the display layer DU may include a display area DA and a non-display area NDA.

The display area DA may be disposed at a center of the display panel 100. A plurality of pixels PX, a plurality of gate lines GL, a plurality of data lines DL, and a plurality of power lines VL may be disposed in the display area DA. Each of the plurality of pixels PX may be defined as a minimum unit emitting light.

The plurality of gate lines GL may supply a gate signal received from a gate driver 210 to the plurality of pixels PX. The plurality of gate lines GL may extend in the first direction DR1 and may be spaced apart from each other in the second direction DR2 intersecting the first direction DR1.

The plurality of data lines DL may supply the data voltage received from the display driver 200 to the plurality of pixels PX. The plurality of data lines DL may extend in the second direction DR2 and may be spaced apart from each other in the first direction DR1.

The plurality of power lines VL may supply the power voltage received from the display driver 200 to the plurality of pixels PX. Here, the power voltage may be at least one of a driving voltage, an initialization voltage, a reference voltage, and a low potential voltage. The plurality of power lines VL may extend in the second direction DR2 and may be spaced apart from each other in the first direction DR1.

The non-display area NDA may surround the display area DA. The gate driver 210, fan-out lines FOL, and gate control lines GCL may be disposed in the non-display area NDA. The gate driver 210 may generate a plurality of gate signals based on the gate control signal, and may sequentially supply the plurality of gate signals to the plurality of gate lines GL according to a set order.

The fan-out lines FOL may extend from the display driver 200 to the display area DA. The fan-out lines FOL may supply the data voltages received from the display driver 200 to the plurality of data lines DL.

The gate control line GCL may extend from the display driver 200 to the gate driver 210. The gate control line GCL may supply the gate control signal received from the display driver 200 to the gate driver 210.

The sub-area SBA may include a display driver 200 and a pad area PA.

The display driver 200 may output signals and voltages for driving the display panel 100 to the fan-out lines FOL. The display driver 200 may supply the data voltage to the data lines DL through the fan-out lines FOL. The data voltage may be supplied to the plurality of pixels PX and may control luminance of the plurality of pixels PX. The display driver 200 may supply the gate control signal to the gate driver 210 through the gate control line GCL.

The pad area PA may be disposed at an edge of the sub-area SBA. The pad area PA may be electrically connected to the circuit board 300 using a material such as, for example, an anisotropic conductive film or self-assembly anisotropic conductive paste (SAP). The pad area PA may include a plurality of display pad portions DP. The plurality of display pad portions DP may be connected to a graphic system through the circuit board 300. The plurality of display pad portions DP may be connected to the circuit board 300 to receive digital video data, and may supply the digital video data to the display driver 200.

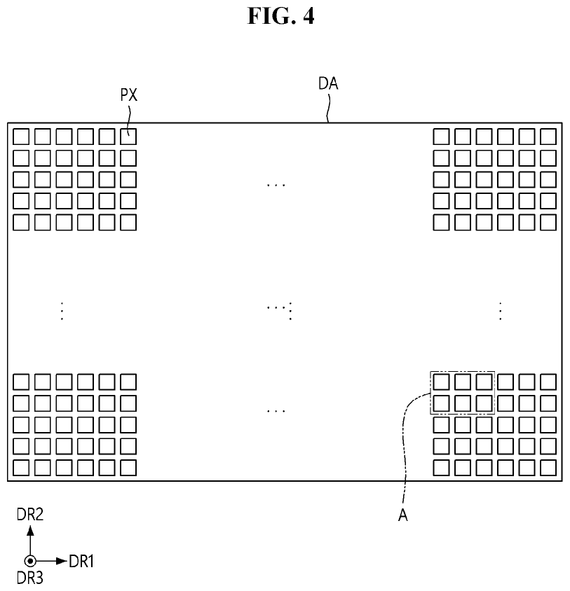

FIG. 4 is a plan view illustrating a display area DA of a display panel 100 according to an embodiment.

Referring to FIG. 4, the display panel 100 may include a plurality of pixels PX arranged in the first direction DR1 and the second direction DR2. Each of the pixels PX may have a planar shape such as, for example, a rectangle, a square, or a rhombus. For example, as illustrated in the drawing, each of the pixels PX may have a planar shape such as, for example, a square. However, each of the pixels PX is not limited thereto, and may have various shapes such as, for example, a polygon, a circle, and an ellipse in a plan view.

Some of the pixels PX may emit first light, others of the pixels PX may emit second light, and the rest of the pixels PX may emit third light. Here, the first light may be light included in a blue wavelength band, the second light may be light included in a red wavelength band, and the third light may be light included in a green wavelength band. The red wavelength band may be a wavelength band of approximately 600 nm to 750 nm, the green wavelength band may be a wavelength band of approximately 480 nm to 560 nm, and the blue wavelength band may be a wavelength band of approximately 370 nm to 460 nm, but the embodiments of the present specification are not limited thereto. In some embodiments, some of the pixels PX may also emit white light.

Each of the pixels PX may include at least one of an organic light emitting element including an organic material, an inorganic light emitting element including an inorganic semiconductor, a quantum dot light emitting element including a quantum dot light emitting layer, and a micro light emitting diode (LED), as a light emitting element emitting light. Hereinafter, it is mainly described that each of the pixels PX includes the organic light emitting element, but the present disclosure is not limited thereto.

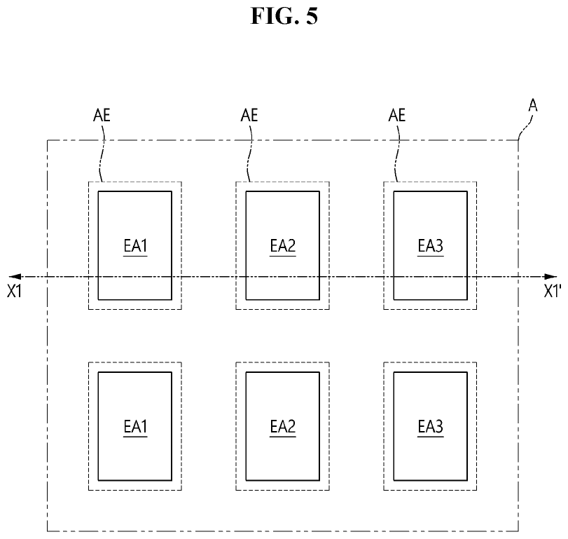

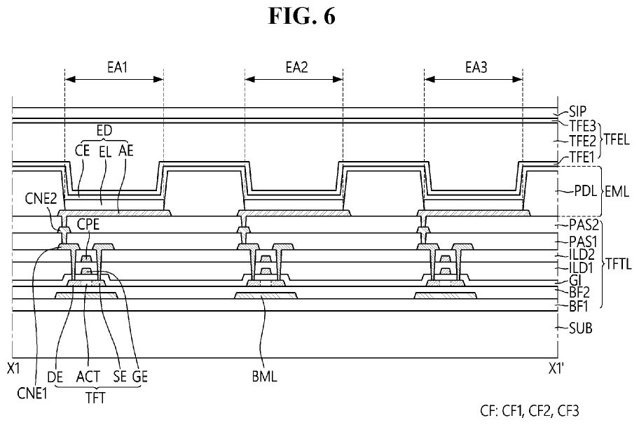

FIG. 5 is an enlarged plan view of an area A of FIG. 4. FIG. 6 is a cross-sectional view taken along line X1-X1′ of FIG. 5.

Referring to FIGS. 5 and 6 together with FIG. 2, the display panel 100 of the display device 10 may include the display layer DU and the passivation layer SIP. The display layer DU may include a substrate SUB, a thin film transistor layer TFTL, a light emitting element layer EML, and an encapsulation layer TFEL. The display panel 100 may include the passivation layer SIP on the encapsulation layer TFEL.

The thin film transistor layer TFTL may be disposed on the substrate SUB. The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film capable of preventing permeation of air or moisture. For example, the first buffer layer BF1 may include a plurality of inorganic films alternately stacked.

The lower metal layer BML may be disposed on the first buffer layer BF1. The lower metal layer BML may prevent light incident from below the lower metal layer BML from being incident on a semiconductor layer ACT of the thin film transistor TFT. The lower metal layer BML may be formed as a single layer or multiple layers of any of molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer BML. The second buffer layer BF2 may include an inorganic film capable of preventing permeation of air or moisture. For example, the second buffer layer BF2 may include a plurality of inorganic films alternately stacked.

The thin film transistor TFT may be disposed on the second buffer layer BF2 and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction, and the semiconductor layer ACT may be insulated from the gate electrode GE by the gate insulating layer GI. In a portion of the semiconductor layer ACT, a material of the semiconductor layer ACT may become a conductor to form the source electrode SE and the drain electrode DE. For example, a conductive material of the semiconductor layer ACT may form the source electrode SE and the drain electrode DE.

The gate electrode GE may be disposed on the gate insulating layer GI. The gate electrode GE may overlap the semiconductor layer ACT, with the gate insulating layer GI interposed between the gate electrode GE and the semiconductor layer ACT.

The gate insulating layer GI may be disposed on the semiconductor layer ACT. For example, the gate insulating layer GI may cover the semiconductor layer ACT and the second buffer layer BF2, and the gate insulating layer GI may insulate the semiconductor layer ACT and the gate electrode GE from each other. The gate insulating layer GI may include a contact hole through which the first connection electrode CNE1 penetrates.

The first interlayer insulating layer ILD1 may cover the gate electrode GE and the gate insulating layer GI. The first interlayer insulating layer ILD1 may include a contact hole through which the first connection electrode CNE1 penetrates. The contact hole of the first interlayer insulating layer ILD1 may be connected to the contact hole of the gate insulating layer GI and a contact hole of the second interlayer insulating layer ILD2.

The capacitor electrode CPE may be disposed on the first interlayer insulating layer ILD1. The capacitor electrode CPE may overlap the gate electrode GE in the thickness direction. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 penetrates. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT and the second connection electrode CNE2 to each other. The first connection electrode CNE1 may be inserted into the contact holes formed in the second interlayer insulating layer ILD2, the first interlayer insulating layer ILD1, and the gate insulating layer GI and be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 penetrates.

The second connection electrode CNE2 may be disposed on the first passivation layer PAS1. The second connection electrode CNE2 may electrically connect the first connection electrode CNE1 and a pixel electrode AE of a light emitting element ED to each other. The second connection electrode CNE2 may be inserted into the contact hole formed in the first passivation layer PAS1 and be in contact with the first connection electrode CNE1.

The second passivation layer PAS2 may cover the second connection electrode CNE2 and the first passivation layer PAS1. The second passivation layer PAS2 may include a contact hole through which the pixel electrode AE of the light emitting element ED penetrates.

The light emitting element layer EML may be disposed on the thin film transistor layer TFTL. The light emitting element layer EML may include light emitting elements ED and a pixel defining film PDL. The light emitting element ED may include a pixel electrode AE, an organic layer EL, and a common electrode CE.

The pixel electrode AE may be disposed on the second passivation layer PAS2. The pixel electrode AE may be disposed to overlap any one of openings OPE1, OPE2, and OPE3 of the pixel defining film PDL. The pixel electrode AE may be electrically connected to the drain electrode DE of the thin film transistor TFT through the first and second connection electrodes CNE1 and CNE2.

The organic layer EL may be disposed on the pixel electrode AE. For example, the organic layer EL may be an organic light emitting layer formed of an organic material, but is not limited thereto. In the case in which the organic layer EL corresponds to the organic light emitting layer, when the thin film transistor TFT applies a predetermined voltage to the pixel electrode AE of the light emitting element ED and the common electrode CE of the light emitting element ED receives a common voltage or a cathode voltage, each of the holes and electrons may move to the organic layer EL through the hole transporting layer and the electron transporting layer, and the holes and electrons may combine with each other in the organic layer EL to emit light.

The common electrode CE may be disposed on the organic layer EL. For example, the common electrode CE may be implemented in the form of an electrode common to all pixels without being divided for each of the plurality of pixels. The common electrode CE may be disposed on the organic layer EL in first to third light emitting areas EA1, EA2, and EA3, and the common electrode CE may be disposed on the pixel defining film PDL in an area excluding the first to third light emitting areas EA1, EA2, and EA3.

The common electrode CE may receive a common voltage or a low potential voltage. In the case in which the pixel electrode AE receives a voltage corresponding to the data voltage and the common electrode CE receives the low potential voltage, a potential difference is formed between the pixel electrode AE and the common electrode CE, and the organic layer EL may emit light.

The pixel defining film PDL may be disposed on the second passivation layer PAS2 and a portion of the pixel electrode AE. The pixel defining film PDL may define the first to third light emitting areas EA1, EA2, and EA3. In an embodiment, the respective areas or sizes of the first to third light emitting areas EA1, EA2, and EA3 may be the same. In another embodiment, the respective areas or sizes of the first to third light emitting areas EA1, EA2, and EA3 may be different from each other. For example, the area of the first light emitting area EA1 may be greater than the area of each of the second light emitting area EA2 and the third light emitting area EA3, and the area of the second light emitting area EA2 may be greater than the area of the third light emitting area EA3. Intensities of light emitted from the light emitting areas EA1, EA2, and EA3 may vary depending on the sizes (e.g., areas) of the light emitting areas EA1, EA2, and EA3, and a color of a screen displayed on the display device 10 may be controlled by adjusting the sizes (e.g., areas) of the light emitting areas EA1, EA2, and EA3.

The pixel defining film PDL may separate and insulate the pixel electrodes AE of the plurality of light emitting elements ED from each other. The pixel defining film PDL may transmit light or block light. In an example in which the pixel defining film PDL transmits light, the pixel defining film PDL may include polyimide PI. In an example in which the pixel defining film PDL blocks light, the pixel defining film PDL may include a light absorbing material to prevent light reflection. For example, the pixel defining film PDL may include a polyimide (PI)-based binder and a pigment in which red, green, and blue colors are mixed. Alternatively or additionally, the pixel defining film PDL may include a cardo-based binder resin and a mixture of lactam black pigment and blue pigment. Alternatively or additionally, the pixel defining film PDL may include carbon black.

The encapsulation layer TFEL may be disposed on the common electrode CE such that the encapsulation layer TFEL covers the plurality of light emitting elements ED. The encapsulation layer TFEL may include at least one inorganic film to prevent oxygen or moisture from permeating into the light emitting element layer EML. The encapsulation layer TFEL may include at least one organic film to protect the light emitting element layer EML from foreign substances such as, for example, dust.

In an embodiment, the encapsulation layer TFEL may include a first encapsulation layer TFEL1, a second encapsulation layer TFEL2, and a third encapsulation layer TFEL3. The first encapsulation layer TFE1 and the third encapsulation layer TFE3 may be inorganic encapsulation layers, and the second encapsulation layer TFEL2 disposed therebetween may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include an acrylic resin, an epoxy-based resin, polyimide, polyethylene, and the like. For example, the organic encapsulation layer 320 may include an acrylic resin, for example, polymethyl methacrylate or polyacrylic acid. The second encapsulation layer TFE2 may be formed by curing a monomer or applying a polymer.

The passivation layer SIP may be disposed on the encapsulation layer TFEL. The passivation layer SIP may be in direct contact with an upper surface of the third encapsulation layer TFE3 of the encapsulation layer TFEL. The passivation layer SIP may planarize a level difference between lower layers (e.g., third encapsulation layer TFE3), protect the lower layers, and reduce reflection of external light. The passivation layer SIP may be disposed on the display area DA and the non-display area NDA, and may be entirely disposed on the substrate SUB. The passivation layer SIP may include one or more of an acrylic resin, an epoxy resin, and a urethane resin. In an embodiment, the passivation layer SIP may include an acrylic resin, for example, isobornyl acrylate (IBOA).

The passivation layer SIP may have a predetermined thickness for planarization, for example, a thickness of 8 μm to 30 μm. The passivation layer SIP may be formed through an inkjet printing process. For example, the passivation layer SIP may be applied through an inkjet printing process and formed through a UV curing process. In an embodiment, the passivation layer SIP may be finally cured through heat treatment and plasma treatment after the UV curing process.

A surface of the passivation layer SIP may be reformed by plasma treatment. The surface of the passivation layer SIP may have hydrophilicity. The hydrophilicity described herein means a property having excellent affinity for a predetermined solution, and as a property different from the hydrophilicity, hydrophobicity means a property that repels a predetermined solution and does not permeate water well. For example, for a predetermined solution having excellent surface binding capacity with one surface having hydrophilicity, the predetermined solution disposed on one surface having hydrophilicity may have reduced surface tension. In contrast, for a predetermined solution having low surface binding capacity with one surface having hydrophobicity, the predetermined solution disposed on one surface having hydrophobicity may have increased surface tension.

In an example in which the surface of the passivation layer SIP has hydrophobicity, a predetermined solution may have a larger contact angle than when having hydrophilicity. The contact angle may refer to an angle formed between a tangential line of a surface of a predetermined solution and one surface at a point where the predetermined solution is in contact with the one surface on which the predetermined solution is disposed. As hydrophobicity increases or surface tension increases, the contact angle may increase. For example, for a surface having hydrophobicity as described herein, when water is disposed on the surface, a contact angle of water on the surface may range of greater than 90° and less than 180°, but is not limited thereto. In some aspects, for a surface having hydrophilicity, when water is disposed on the surface, a contact angle of water on the surface may range of greater than 0° and less than 90°.

According to one or more embodiments of the present disclosure, the surface of the passivation layer SIP has hydrophilicity, and a contact angle of the surface of the passivation layer SIP with water may range from 5° to 45°. As the surface of the passivation layer SIP has hydrophilicity, a coating solution of a coating layer to be applied to the passivation layer SIP in a manufacturing method described herein may be evenly applied.

Hereinafter, a method of manufacturing the display device described herein will be described with reference to other drawings.

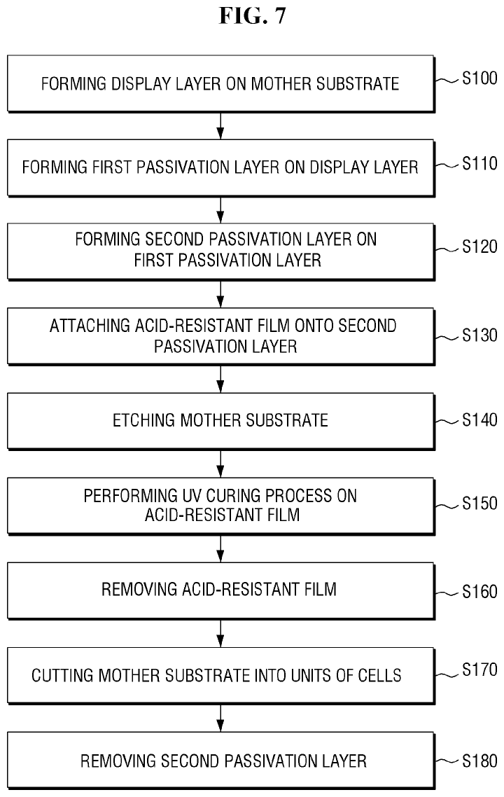

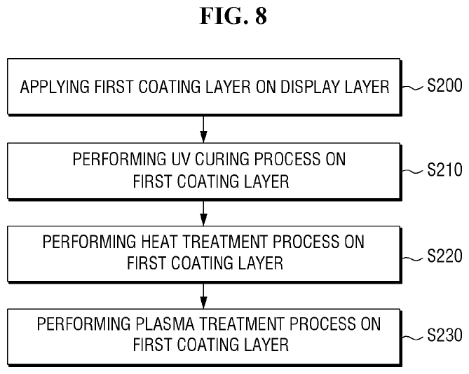

FIG. 7 is a flowchart illustrating a method for manufacturing a display device according to an embodiment. FIG. 8 is a flowchart illustrating steps of forming a first passivation layer according to an embodiment.

Referring to FIGS. 7 and 8, a method for manufacturing a display device according to an embodiment may include forming a display layer DU on a mother substrate MSUB (S100), forming a first passivation layer SIP on the display layer DU (S110), forming a second passivation layer DIP on the first passivation layer SIP (S120), attaching an acid-resistant film UNF on the second passivation layer DIP (S130), etching the mother substrate MSUB (S140), performing a UV curing process on the acid-resistant film UNF (S150), removing the acid-resistant film UNF (S160), cutting the mother substrate MSUB into units of cells (S170), and removing the second passivation layer DIP.

In some embodiments, the forming of the first passivation layer SIP on the display layer DU (S110) may include applying a first coating layer COL1 on the display layer DU (S200), performing a UV curing process on the first coating layer COL1 (S210), performing a heat treatment process on the first coating layer COL1 (S220), and performing a plasma treatment process on the first coating layer COL1 (S230).

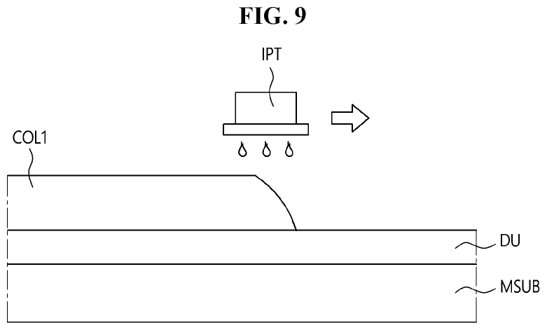

FIGS. 9 to 20 are views illustrating example processes of a method for manufacturing a display device according to an embodiment.

Hereinafter, a method of manufacturing a display device of FIGS. 9 to 20 will be described in connection with FIGS. 7 and 8.

Referring to FIG. 9, the method may include forming a display layer DU on a mother substrate MSUB (S100). As described herein, the mother substrate MSUB may be a glass substrate. The mother substrate MSUB may be a substrate in which a cell area in which units of a plurality of cells are to be formed is formed in order to obtain a plurality of display devices 10 at once. The cell area may be an area corresponding to one display device 10. The mother substrate MSUB may be a substrate SUB, and aspects of the present disclosure support cutting the mother substrate MSUB into units of cells through a cutting process described later herein. A plurality of display devices may be arranged and disposed in a grid pattern on the mother substrate MSUB.

The display layer DU may be disposed in a plurality of cell areas. The display layer DU is as described herein with reference to FIG. 6, and since a process of forming the display layer DU is widely known to those skilled in the art, a detailed description thereof will be omitted. In the following drawings, one cell area will be illustrated and described, and example aspects described with reference to the cell area may be applied to a plurality of cell areas described herein.

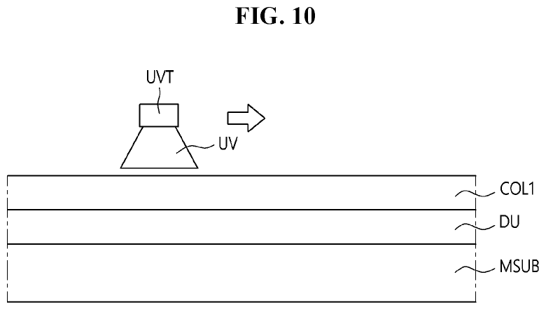

Referring to FIG. 10, the method may include forming a first passivation layer SIP on the display layer DU (S110). The first passivation layer SIP may be formed by applying a coating of a first coating layer COL1 on the display layer DU.

Specifically, for example, the method may include applying a first coating layer COL1 onto the display layer DU (S200). The first coating layer COL1 may be formed by applying a coating solution for forming the first passivation layer SIP. The coating solution may include an acrylic resin, for example, isobornyl acrylate (IBOA). In some embodiments, the coating solution may include a photoinitiator, solvent, additives, and the like. The method may include forming the first coating layer COL1 through an inkjet printing process. For example, the method may include forming the first coating layer COL1 by aligning an inkjet device IPT on the display layer DU and spraying the coating solution while the inkjet device IPT moves in one direction. The first coating layer COL1 may be formed to have a thickness of 8 μm to 30 μm.

Referring to FIG. 10, the method may include performing a UV curing process on the first coating layer COL1 (S210). In the UV curing process, the method may include emitting UV light (e.g., irradiating the first coating layer COL1 with UV light) while aligning a UV emission device UVT on the first coating layer COL1 and moving the UV emission device UVT in one direction. In an embodiment, the first coating layer COL1 is an air curing type, and the UV curing process may be performed in an air atmosphere at room temperature. In some embodiments, the UV curing process may use a UV lamp light source capable of emitting light of 365 nm, 385 nm, or 395 nm wavelength, and in this example case, the UV lamp light source may emit UV light singly or in combination with one or more other UV lamp light sources (not illustrated). In some embodiments, a cumulative amount of the UV light associated with the UV curing process may be in the range of 0.5 J to 3 J. The first coating layer COL1 may be cured in the UV curing process.

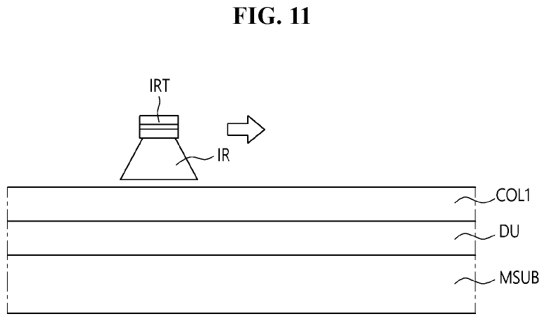

Referring to FIG. 11, the method may include performing a heat treatment process on the first coating layer COL1 (S220). The heat treatment process may be performed using an oven or infrared ray (IR) emission device. For example, the method may include emitting IR light (e.g., irradiating the first coating layer COL1 with IR light) while aligning the IR emission device IRT (also referred to herein as IR irradiation device IRT) on the first coating layer COL1 and moving the IR emission device IRT in one direction. The heat treatment process may be performed for about 10 minutes to about 40 minutes at a temperature range of 70° C. to 90° C.

In the present embodiment, as the heat treatment process is performed after the UV curing process, some unreacted materials in the first coating layer COL1 in the UV curing process may be crosslinked and residual solvent may be removed. Therefore, for example, a curing rate of the first coating layer COL1 may be improved.

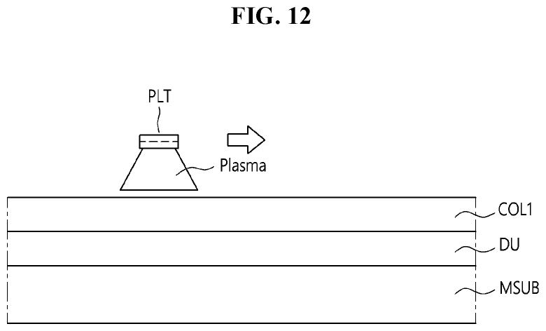

Referring to FIG. 12, the method may include performing a plasma treatment process on the first coating layer COL1 (S230). The method may include performing the plasma treatment process in an atmospheric pressure or vacuum atmosphere. The plasma treatment process may use N₂ or O₂ plasma, and in some example embodiments, N₂ plasma. In the present embodiment, N₂ plasma will be described as an example.

In the plasma treatment process, the method may include irradiating plasma while aligning a plasma device PLT on the first coating layer COL1 and moving the plasma device PLT in one direction. The method may include performing the plasma treatment process under a power in the range of 1 kilowatt (kW) to 5 kW, a voltage in the range of 11 kilovolts (kV) to 15 kV, and a speed of 60 millimeters (mm)/seconds (s) to 260 mm/s. In this example case, a flow rate of N₂ gas is in the range of 200 liters per minute (LPM) to 1200 LPM, and a flow rate of clean dry air (CDA) may be in the range of 2 LPM to 9 LPM. For example, in some embodiments, the plasma treatment process may be performed under conditions in which the flow rate of N₂ gas is in the range of 200 LPM to 1200 LPM and the flow rate of clean dry air (CDA) is in the range of 2 LPM to 9 LPM.

When the plasma treatment process is performed on the first coating layer COL1, unreacted materials remaining on the surface of the first coating layer COL1 may be removed and surface energy may be improved. As the unreacted materials of the first coating layer COL1 are removed, the curing rate of the first coating layer COL1 may be further improved. In some aspects, since the surface energy of the first coating layer COL1 is improved, the surface of the first coating layer COL1 may have hydrophilicity.

As described herein, as the UV curing process, the heat treatment process, and the plasma treatment process are performed on the first coating layer COL1, the first passivation layer SIP as formed by the processes may have an improved curing rate.

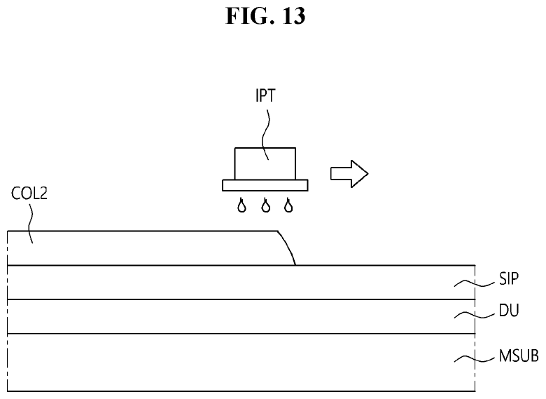

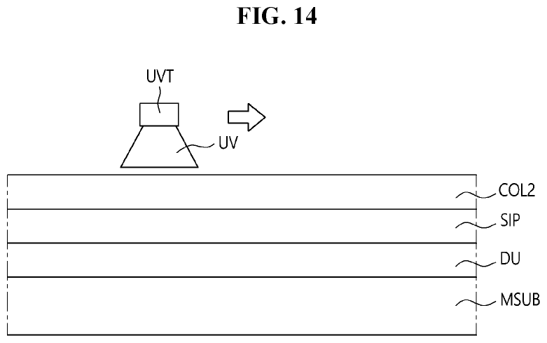

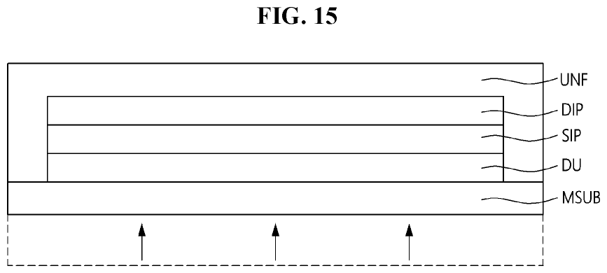

Referring to FIGS. 13 and 14, the method may include forming a second passivation layer DIP (later illustrated at FIG. 15) on the first passivation layer SIP (S120). Specifically, for example, the method may include forming the second passivation layer DIP through a UV curing process after a second coating layer COL2 is applied onto the first passivation layer SIP. The second coating layer COL2 may act as a passivation layer capable of protecting layers on a lower side of the second coating layer COL2.

The second coating layer COL2 may include an acrylic resin similar to or the same as the acrylic resin described with reference to the first coating layer COLL. The method may include applying the second coating layer COL2 through an inkjet printing process. For example, the method may include applying the second coating layer COL2 to a thickness of 80 μm to 150 μm using an inkjet device IPT (e.g., such that the thickness of the second coating layer COL2 is 80 μm to 150 μm). The UV curing process of the second coating layer COL2 may be performed using a UV emission device UVT. The UV curing process of the second coating layer COL2 may be performed under similar or identical UV curing conditions to those of the aforementioned first coating layer COLL.

Referring to FIG. 15, the method may include attaching an acid-resistant film UNF onto the second passivation layer DIP (S130). The acid-resistant film UNF serves to prevent the display layer DU from being damaged by an etchant in a process of etching the mother substrate MSUB, example aspects of which will be described later herein. The method may include attaching the acid-resistant film UNF such that the acid-resistant film UNF completely covers the display layer DU, the first passivation layer SIP, and the second passivation layer DIP disposed on the mother substrate MSUB. The process of attaching the acid-resistant film UNF may be performed as a laminating process. The method may include adhering the acid-resistant film UNF to the mother substrate MSUB, the display layer DU, the first passivation layer SIP, and the second passivation layer DIP through an adhesive, such as, for example, a pressure sensitive adhesive (PSA).

The method may include etching the mother substrate MSUB (S140). In the process of etching the mother substrate MSUB, the method may include reducing a thickness of the mother substrate MSUB by spraying an etchant on the mother substrate MSUB. When the etchant is sprayed onto the mother substrate MSUB, the thickness of the mother substrate MSUB may be reduced, and the display layer DU may be protected from the etchant by the acid-resistant film UNF.

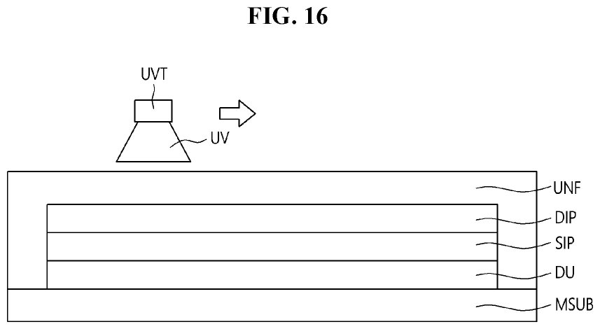

Referring to FIG. 16, the method may include performing a UV curing process on the acid-resistant film UNF (S150). When the acid-resistant film UNF is irradiated with UV, the PSA may be UV-cured and adhesion may be reduced. That is, for example, by irradiating the acid-resistant film UNF with UV in the UV curing process, the adhesion of the PSA is reduced, such that peeling of the acid-resistant film UNF described later may be easily performed. For example, the reduced adhesion of the PSA supports a more effective peeling of the acid-resistant film UNF. The UV curing process may be performed by emitting UV light (e.g., irradiating the acid-resistant film UNF with UV light) while moving a UV emission device UVT in one direction. It is to be understood that references to easier performing of peeling of a film from another film may refer to a reduction or prevention of damage (e.g., tearing) to the film and/or the other film.

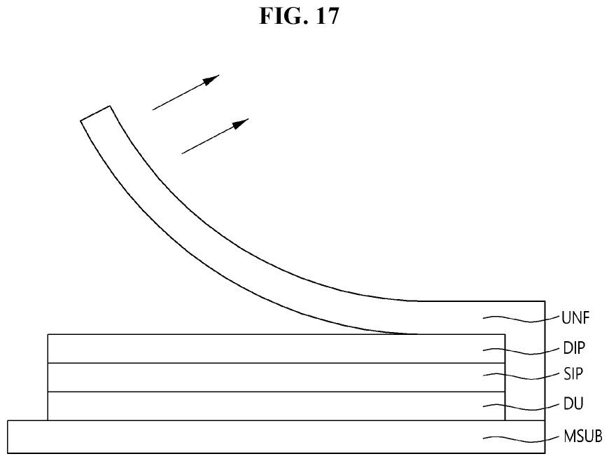

Referring to FIG. 17, the method may include removing the acid-resistant film UNF (S160). The method may include peeling and removing the acid-resistant film UNF using a peeling device. The acid-resistant film UNF may be peeled when the PSA having reduced adhesion is separated from the mother substrate MSUB, the display layer DU, the first passivation layer SIP, and the second passivation layer DIP.

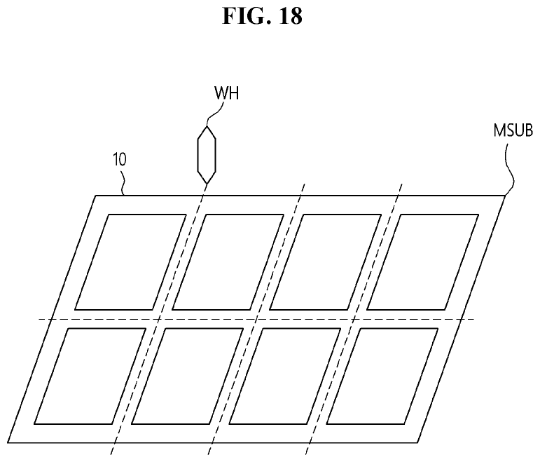

Referring to FIG. 18, the method may include cutting the mother substrate MSUB into units of cells (S170). The method may include cutting the mother substrate MSUB into units of a plurality of cells. The cutting process may be performed using a wheel or a laser. Through the cutting process, the plurality of display devices 10 into units of cells may be separated from the mother substrate MSUB.

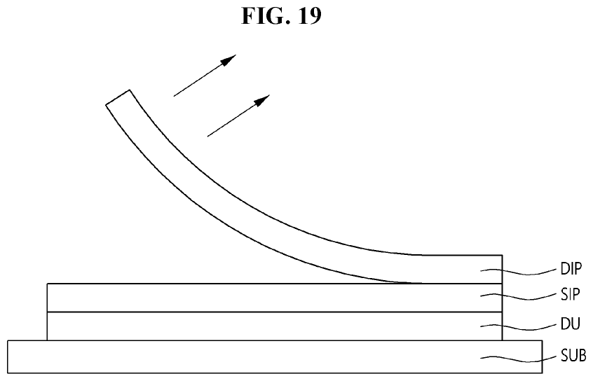

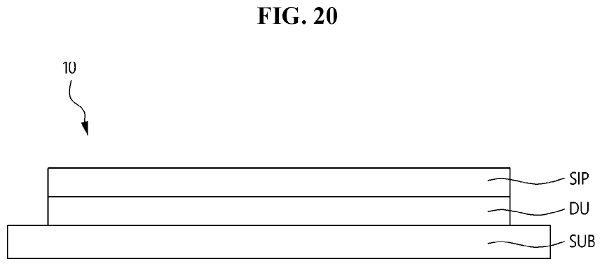

Referring to FIGS. 19 and 20, the method may include removing the second passivation layer DIP (S180). The display device 10 separated from the mother substrate MSUB may include the display layer DU, the first passivation layer SIP, and the second passivation layer DIP on the substrate SUB. The second passivation layer DIP serves as a passivation layer for protecting lower layers among the above-described processes, and in some embodiments, the method may include removing the second passivation layer DIP after the above-described processes are performed.

In some cases, when the curing rate of the above-described first passivation layer SIP is low, an uncured material of the first passivation layer SIP may be coupled to the second passivation layer DIP during a UV irradiation process of the second passivation layer DIP. That is, for such example cases, since the first passivation layer SIP and the second passivation layer DIP are coupled to each other, the first passivation layer SIP may be torn or the encapsulation layer TFEL may be torn together with the first passivation layer SIP when the second passivation layer DIP is peeled off, due to the uncured material.

By improving the curing rate of the first passivation layer SIP through the UV curing process, the heat treatment process, and the plasma treatment process according to the example embodiments described herein, when the second passivation layer DIP is peeled off, the first passivation layer SIP may be prevented from being torn.

Accordingly, the display device 10 in which the display layer DU and the first passivation layer SIP are disposed on the substrate SUB may be manufactured by removing the second passivation layer DIP.

Hereinafter, a method for manufacturing a display device according to another embodiment will be described with reference to other drawings.

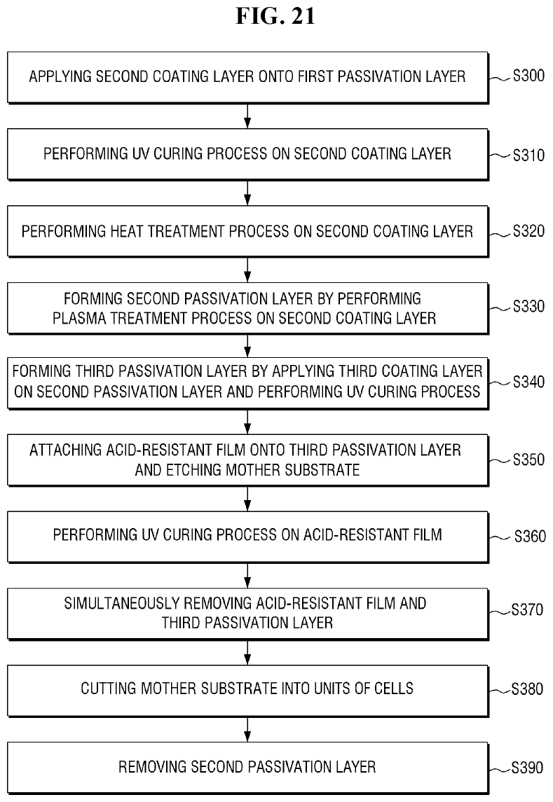

FIG. 21 is a flowchart illustrating a method for manufacturing a display device according to another embodiment. In some embodiments, the manufacturing method of FIG. 21 is performed after forming the first passivation layer on the display layer of FIGS. 7 and 8 described herein (S110). Hereinafter, descriptions overlapping with those of the above-described embodiments will be omitted or simplified.

Referring to FIG. 21, the method for manufacturing a display device according to another embodiment may include applying a second coating layer COL2 on a first passivation layer SIP (S300), performing a UV curing process on the second coating layer COL2 (S310), performing a heat treatment process on the second coating layer COL2 (S320), forming a second passivation layer DIP1 by performing a plasma treatment process on the second coating layer COL2 (S330), forming a third passivation layer DIP2 by applying a third coating layer COL3 on the second passivation layer DIP1 and performing a UV curing process S340, attaching an acid-resistant film UNF onto the third passivation layer DIP2 and etching the mother substrate MSUB (S350), performing a UV curing process on the acid-resistant film UNF (S360), simultaneously removing the acid-resistant film UNF and the third passivation layer DIP2 (S370), cutting the mother substrate MSUB into units of cells (S380), and removing the second passivation layer DIP1 (S390).

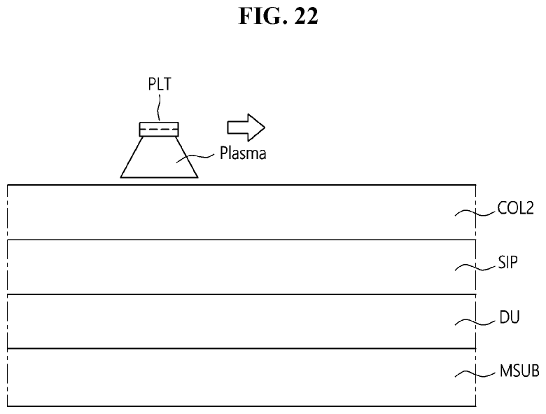

FIGS. 22 to 26 are views illustrating example processes of a method for manufacturing a display device according to another embodiment.

Hereinafter, the method of manufacturing a display device of FIGS. 22 to 26 will be described in connection with FIG. 21.

Referring to FIG. 22, the method may include applying a second coating layer COL2 on a first passivation layer SIP (S300). As described herein with reference to FIGS. 10 to 12, the first passivation layer SIP may be formed by performing the UV curing process, the heat treatment process, and the plasma treatment process. The second coating layer COL2 may be applied onto the mother substrate MSUB. For example, the second coating layer COL2 may be applied on an upper surface of the first passivation layer SIP among the display layer DU and the first passivation layer SIP sequentially formed on the mother substrate MSUB.

The second coating layer COL2 may include an acrylic resin similar to or the same as the acrylic resin described with reference to the first passivation layer SIP. The method may include applying the second coating layer COL2 through an inkjet printing process. For example, the second coating layer COL2 may be applied to a thickness of 80 μm to 150 μm using an inkjet device (e.g., applied such that a thickness of the second coating layer COL2 is of 80 μm to 150 μm). STOP

The method may include performing a UV curing process on the second coating layer COL2 (S310), performing a heat treatment process on the second coating layer COL2 (S320), and forming a second passivation layer DIP1 (S330) by performing a plasma process on the second coating layer COL2.

The UV curing process, heat treatment process, and plasma treatment process of the second coating layer COL2 may be performed similarly or substantially the same as the UV curing process, heat treatment process, and plasma treatment process of the first coating layer COL1 described with reference to FIGS. 10 to 12 described herein. For example, the UV curing process may be performed using a UV emission device, the heat treatment process may be performed using an IR emission device, and the plasma treatment process may be performed by irradiating N₂ plasma through a plasma device PLT.

In some aspects, the techniques described herein of performing the UV curing process, the heat treatment process, and the plasma treatment process on each of the first passivation layer SIP and the second passivation layer DIP1 may improve a curing rate of each of the first passivation layer SIP and the second passivation layer DIP1. In particular, the improved curing rate of the second passivation layer DIP1 may prevent or reduce peeling defects between the second passivation layer DIP1 and a third passivation layer DIP2 described later herein.

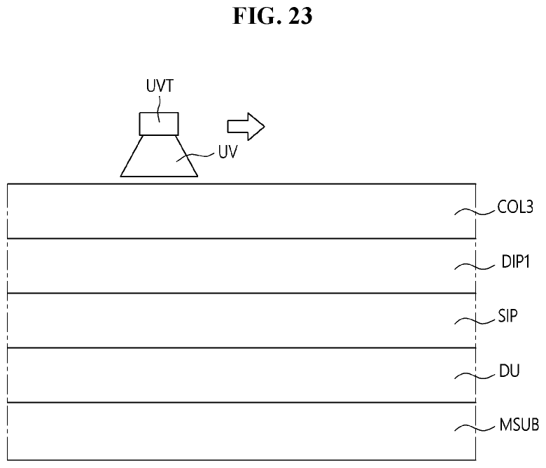

Referring to FIG. 23, the method may include forming a third passivation layer DIP2 by applying a third coating layer COL3 on the second passivation layer DIP1 and performing a UV curing process (S340). The method may include forming the third coating layer COL3 by applying a material through an inkjet printing process, in which the material is similar to or the same as the material applied for forming the second passivation layer DIP1. The method may include curing the third coating layer COL3 by irradiating the third coating layer COL3 with UV light in an energy range of 0.5 J to 3 J using a UV emission device. In some examples, different from the above-described curing of first passivation layer SIP and second passivation layer DIP1, the third coating layer COL3 may be cured through the UV curing process, and without other processes described with reference to the curing of the first passivation layer SIP and the second passivation layer DIP1, to form the third passivation layer DIP2. Accordingly, for example, since adhesion between the third passivation layer DIP2 and the second passivation layer DIP1 is relatively low, the third passivation layer DIP2 may be easily peeled from the second passivation layer DIP1 when an acid-resistant film UNF described later is peeled off.

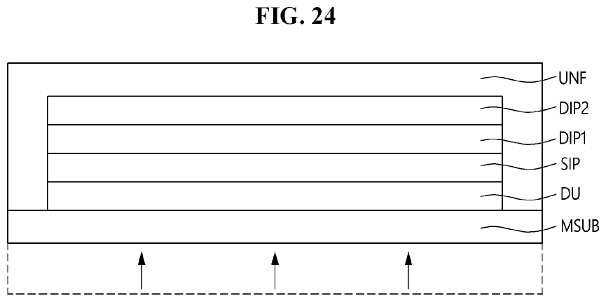

Referring to FIG. 24, the method may include attaching an acid-resistant film UNF onto the third passivation layer DIP2 and etching the mother substrate MSUB (S350). The method may include attaching the acid-resistant film UNF such that the acid-resistant film UNF completely covers the display layer DU, the first passivation layer SIP, the second passivation layer DIP1, and the third passivation layer DIP2 disposed on the mother substrate MSUB. In some embodiments, the process of attaching the acid-resistant film UNF may be performed as a laminating process.

In the process of etching the mother substrate MSUB, the method may include reducing a thickness of the mother substrate MSUB by spraying an etchant on the mother substrate MSUB. When the etchant is sprayed onto the mother substrate MSUB, the thickness of the mother substrate MSUB may be reduced, and the display layer DU may be protected from the etchant by the acid-resistant film UNF.

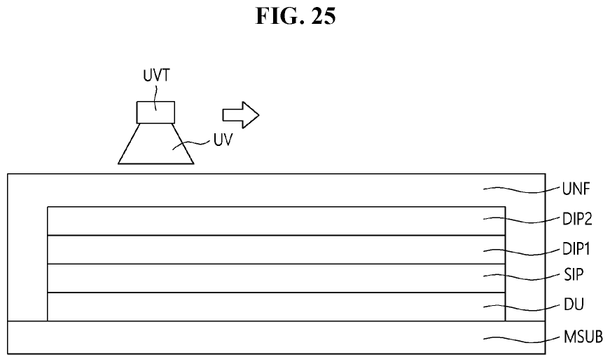

Referring to FIG. 25, the method may include performing a UV curing process on the acid-resistant film UNF (S360). When the acid-resistant film UNF is irradiated with UV light, PSA disposed on one surface of the acid-resistant film UNF is UV cured and adhesion thereof is reduced, such that peeling of the acid-resistant film UNF may be easily performed. The UV curing process may be performed by emitting UV light (irradiating the acid-resistant film UNF with UV light) while moving a UV emission device UVT in one or more directions (e.g., one direction).

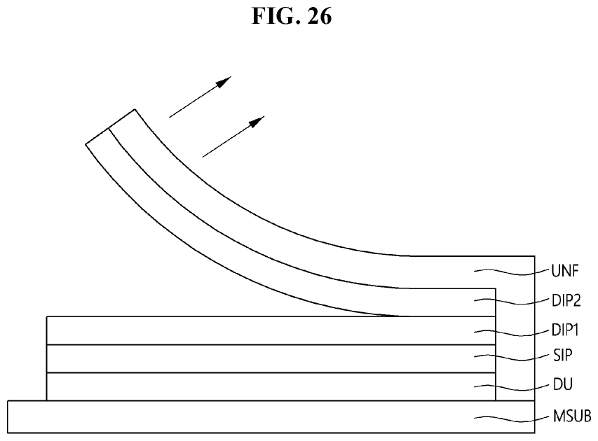

Referring to FIG. 26, the method may include simultaneously removing the acid-resistant film UNF and the third passivation layer DIP2 (S370). The method may include peeling and removing the acid-resistant film UNF using a peeling device. When the acid-resistant film UNF is peeled off, the third passivation layer DIP2 may be peeled along with the acid-resistant film UNF. As described herein, since the curing rate of the third passivation layer DIP2 is relatively low, the third passivation layer DIP2 may be easily separated from the second passivation layer DIP1. Accordingly, the third passivation layer DIP2 adhered to the acid-resistant film UNF may be peeled together with the acid-resistant film UNF when the acid-resistant film UNF is peeled off.

A display device according to an embodiment may be manufactured by cutting the mother substrate MSUB into units of cells (S380) and removing the second passivation layer DIP1 (S390). Since the cutting process and the process of removing the second passivation layer DIP2 have been described with reference to FIGS. 18 to 20, the descriptions thereof will be omitted.

In some cases, when the curing rate of the above-described first passivation layer SIP is low, an uncured material of the first passivation layer SIP may be combined with the second passivation layer DIP during a UV irradiation process of the second passivation layer DIP1. Accordingly, when the acid-resistant film UNF is peeled off, the first passivation layer SIP and the second passivation layer DIP may be torn together. According to one or more embodiments of the present disclosure described herein, the curing rate may be improved by performing the UV curing process, the heat treatment process, and the plasma treatment process on each of the first passivation layer SIP and the second passivation layer DIP1, and the first passivation layer SIP and the second passivation layer DIP may be prevented from being damaged by further forming the third passivation layer DIP2 on the second passivation layer DIP1, which supports simultaneously peeling the third passivation layer DIP2 when the acid-resistant film UNF is peeled off.

Table 1 below shows example results of performing the UV curing process, the heat treatment process, and the plasma treatment process on the first passivation layer, forming the second passivation layer on the first passivation layer, and then peeling the second passivation layer.

TABLE 1

| | Process Conditions for First Passivation Layer | | | |
|---|---|---|---|---|
| | Cumulative | | Plasma | — |
| | Amount of UV | Heat | Treatment | Peeling Result of Second |
| / | Light (J) | Treatment | (Yes/No) | Passivation Layer |
| #1 | 1.5 | No | No | Simultaneous Peeling of First |
| | | | | Passivation Layer and Second |
| | | | | Passivation Layer |
| #2 | 1.5 | No | Yes | Simultaneous Peeling of First |
| | | | | Passivation Layer and Second |
| | | | | Passivation Layer |
| #3 | 6 | No | Yes | Tearing of Second Passivation |
| | | | | Layer |
| #4 | 6 | No | Yes | Tearing of Second Passivation |
| | | | | Layer |
| #5 | 1.5 | 80° C./30 | No | Peeling of Encapsulation Layer |
| | | min | | and Tearing of Second |
| | | | | Passivation Layer |
| #6 | 6 | 80° C./30 | No | Peeling of Encapsulation Layer |
| | | min | | and Tearing of Second |
| | | | | Passivation Layer |
| #7 | 1.5 | 80° C./30 | Yes | Good Peeling of Second |
| | | min | | Passivation Layer |
| #8 | 1.5 | 60° C./30 | Yes | Tearing of Second Passivation |
| | | min | | Layer |

Referring to Table 1 above, when the first passivation layer is formed by performing a UV curing process of 1.5 J, a heat treatment process of 80° C./30 minutes, and a plasma treatment process as in #7, it was confirmed that the second passivation layer was well peeled off without damaging the first passivation layer. In contrast, for example, in other process conditions, the second passivation layer was torn, such that the peeling was not properly performed (e.g., the first passivation layer was damaged as a result of peeling off the second passivation layer) or the first passivation layer and the encapsulation layer were peeled off together.

Table 2 below shows a contact angle between a surface of the first passivation layer and water before and after plasma treatment.

Specifically, for example, an acrylic resin was coated on the substrate, and UV curing, heat treatment, and plasma treatment processes were performed. In this example case, the plasma treatment process was performed at different speeds of 60 mm/s and 250 mm/s, respectively.

TABLE 2

| | Contact Angle of Surface (°) | | | |
|---|---|---|---|---|
| | | After Plasma | After Plasma | Range of |
| | Before Plasma | Treatment (60 | Treatment (250 | Contact |
| / | Treatment | mm/s) | mm/s) | Angle |
| First | 83.77 | 6.00 | 41.30 | 5~45 |
| Passivation | | | | |
| Layer | | | | |

Referring to Table 2 above, it was confirmed that when the plasma treatment process was performed on the surface of the first passivation layer, the contact angle between the surface of the first passivation layer and water ranged from 5 to 45°. Through this result, it may be seen that as a result of performing the plasma treatment process on the surface of the first passivation layer as described herein, the surface has hydrophilicity.

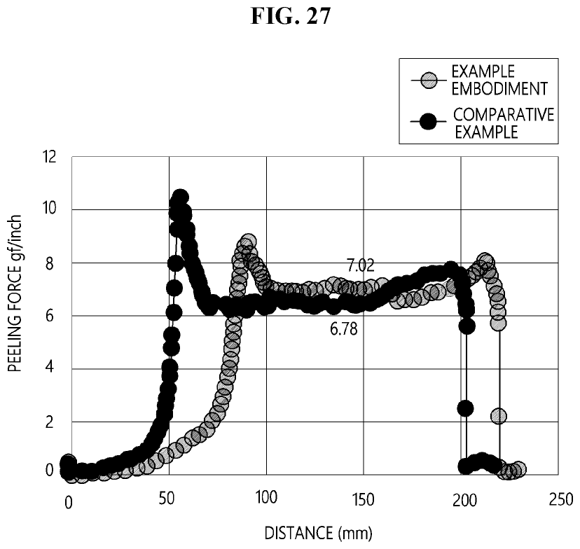

FIG. 27 is a graph illustrating a peeling force between a first passivation layer and a second passivation layer according to distance from an end of the first passivation layer. In FIG. 27, in the comparative example, a PET film was formed as the second passivation layer, and in the example embodiment, the second passivation layer was formed by applying a coating of an acrylic resin through an inkjet printing process. In the example embodiment, a UV curing process, a heat treatment process, and a plasma treatment process were performed on the first passivation layer according to process conditions illustrated in #7 of Table 1 above.

Referring to FIG. 27, in an area of the graph corresponding to a distance range of 100 mm to 200 mm from an end of the first passivation layer, a peel force of the second passivation layer was about 7.02 gf/inch and 6.78 gf/inch in the example embodiment and the comparative example, respectively, showing similar levels to each other.

Through this result, in the example embodiment in which the UV curing process, the heat treatment process, and the plasma treatment process are performed on the first passivation layer and the second passivation layer is formed by the inkjet printing process, it was confirmed that the second passivation layer was easily separated due to a weak peeling force as in the comparative example in which the PET film was attached onto the first passivation layer.

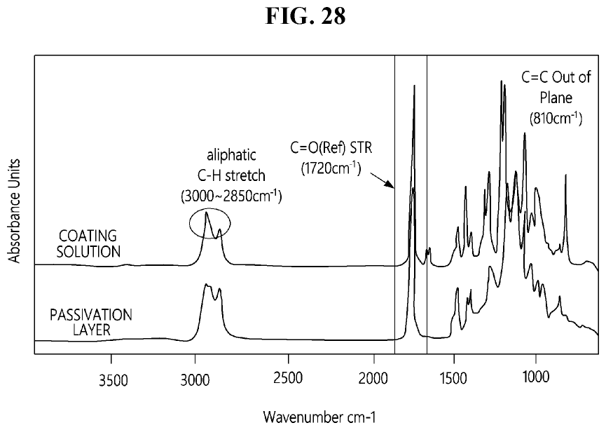

FIG. 28 is a graph of FT-IR analysis of a coating solution and a passivation layer. In FIG. 28, the horizontal axis represents the wavenumber and the vertical axis represents absorbance units.

Referring to FIG. 28, it may be seen that the absorbance units of the passivation layer are lowered compared to the absorbance units of the coating solution at a wavenumber of 1230 cm⁻¹ showing C—O bonding, a wavenumber of 1120 cm⁻¹ showing C—O—C bonding, and a wavenumber of 810 cm⁻¹ showing C═C bonding. A curing rate of the passivation layer may be obtained by calculating a ratio of the absorbance units of the passivation layer to the absorbance units of the coating solution at each wavenumber. Through this, it may be seen that the curing rate of the passivation layer formed by performing the UV curing process, the heat treatment process, and the plasma treatment process on the coating solution was increased.

In concluding the detailed description, those skilled in the art will appreciate that many variations and modifications can be made to the example embodiments without substantially departing from the principles of the present invention. Therefore, the disclosed example embodiments of the invention are used in a generic and descriptive sense only and not for purposes of limitation.

What is claimed is:

1. A display device comprising:
a substrate;
a light emitting element layer disposed on the substrate and including a pixel electrode, an organic layer, and a common electrode;
an encapsulation layer disposed on the light emitting element layer; and
a passivation layer disposed on the encapsulation layer,
wherein a contact angle between a surface of the passivation layer and water ranges from 5° to 45°.

2. The display device of claim 1, wherein the surface of the passivation layer has hydrophilicity.

3. The display device of claim 1, wherein the passivation layer includes one or more of an acrylic resin, an epoxy resin, and a urethane resin.

4. The display device of claim 1, wherein the passivation layer is formed to have a thickness of 8 μm to 30 μm.

5. The display device of claim 1, wherein the encapsulation layer includes a first encapsulation layer disposed on the light emitting element layer, a second encapsulation layer disposed on the first encapsulation layer, and a third encapsulation layer disposed on the second encapsulation layer, and
the passivation layer is in contact with an upper surface of the third encapsulation layer.

6. A method for manufacturing a display device, the method comprising:
forming a display layer on a mother substrate;
applying a first coating layer on the display layer;
forming a first passivation layer by sequentially performing a first UV curing process, a heat treatment process, and a plasma treatment process on the first coating layer; and
forming a second passivation layer on the first passivation layer,
wherein the plasma treatment process uses N₂ plasma.

7. The method of claim 6, wherein the first coating layer is applied through an inkjet printing process.

8. The method of claim 6, wherein the first coating layer is applied such that a thickness of the first coating layer is 8 μm to 30 μm.

9. The method of claim 6, wherein a cumulative amount of light of the first UV curing process is 0.5 J to 3 J.

10. The method of claim 6, wherein the heat treatment process is performed for 10 minutes to 40 minutes at a temperature range of 70° C. to 90° C.

11. The method of claim 6, wherein the plasma treatment process is performed at a power of 1 kW to 5 kW, a voltage of 11 kV to 15 kV, and a speed of 60 mm/s to 260 mm/s.

12. The method of claim 6, wherein a flow rate of N₂ gas of the N₂ plasma is 200 LPM to 1200 LPM.

13. The method of claim 6, wherein the second passivation layer is formed by applying a second coating layer on the first passivation layer and performing a second UV curing process.

14. The method of claim 6, further comprising:
attaching an acid-resistant film onto the second passivation layer;
etching the mother substrate;
performing a third UV curing process on the acid-resistant film;
removing the acid-resistant film;
cutting the mother substrate into units of cells; and
removing the second passivation layer.

15. The method of claim 14, wherein the etching of the mother substrate comprises spraying an etchant on the mother substrate to reduce a thickness of the mother substrate.

16. A method for manufacturing a display device, the method comprising:
forming a display layer on a mother substrate;
forming a first passivation layer by applying a first coating layer on the display layer and sequentially performing a first UV curing process, a first heat treatment process, and a first plasma treatment process on the first coating layer;
forming a second passivation layer by applying a second coating layer on the first passivation layer and sequentially performing a second UV curing process, a second heat treatment process, and a second plasma treatment process on the second coating layer; and
forming a third passivation layer on the second passivation layer,
wherein the first plasma treatment process and the second plasma treatment process use N₂ plasma.

17. The method of claim 16, wherein the first plasma treatment process and the second plasma treatment process are performed at a power of 1 kW to 5 kW, a voltage of 11 kV to 15 kV, and a speed of 60 mm/s to 260 mm/s.

18. The method of claim 16, wherein a flow rate of N₂ gas of the N₂ plasma is 200 LPM to 1200 LPM.

19. The method of claim 16, further comprising:
attaching an acid-resistant film onto the third passivation layer and etching the mother substrate;
performing a third UV curing process on the acid-resistant film;
simultaneously removing the acid-resistant film and the third passivation layer;
cutting the mother substrate into units of cells; and
removing the second passivation layer.

20. The method of claim 16, wherein forming the third passivation layer comprises applying a third coating layer on the first passivation layer, and wherein the first coating layer, the second coating layer, and the third coating layer are each applied through an inkjet printing process.
